(19) United States
(12) Patent Application Publication
(10) Pub. No.: US 2005/0020043 A1
(43) Pub. Date: Jan. 27, 2005

(54) Methods for reducing cell pitch in semiconductor devices

(76) Inventor: Jiun-Ren Lai, Hsinchu (TW)

Correspondence Address: Kenton R. Mullins;Stout, Uxa, Buyan & Mullins, LLP, Suite 300, 4 Venture, Irvine, CA, 92618, US

(21) Appl. No.: 10/627,115

(22) Filed: Jul. 25, 2003

(51) Int. Cl. H01L 27/10; H01L 21/3205; H01L 21/4763

(52) U.S. Cl. 438/587; 438/585; 438/596

(57) ABSTRACT

A method for forming a semiconductor device having a reduced pitch is provided. A pad oxide layer is formed on a substrate, and a silicon nitride layer is formed on the pad oxide layer. A trimmed photoresist layer is formed on the silicon nitride layer, and the silicon nitride layer is etched using the trimmed photoresist layer as an etch mask. The trimmed photoresist layer is removed until the silicon nitride layer is completely exposed, and an exposed portion of the pad oxide layer is removed until a portion of the substrate is exposed. A gate oxide layer is formed on the exposed portion of the substrate. A poly layer is deposited on the silicon nitride layer, and the poly layer is etched back to form a plurality of poly gates. Then, the silicon nitride layer is removed.

### BACKGROUND OF THE INVENTION

1. Field of the Invention

The present invention relates generally to methods for fabricating semiconductor devices and, more particularly, to methods for reducing the cell pitch in semiconductor devices.

2. Description of Related Art

Modern integrated circuit devices contain numerous structures that comprise conductive material, semi-conductive material (i.e., rendered conductive in defined areas with dopants), and/or non-conductive material. For example, transistor devices are commonly fabricated by forming a semi-conductive material, such as polycrystalline silicon (polysilicon), over a relatively thin gate dielectric arranged upon a semiconductor substrate. The polysilicon material is patterned to define gate conductors spaced laterally apart above the substrate. Along with the gate conductors, exposed regions of the substrate are implanted with impurity dopants to form source/drain junctions in the substrate between the gate conductors. If the dopant species employed for forming the source/drain regions is n-type, then an NMOSFET (n-channel) transistor device is formed. Conversely, if the source/drain dopant species employed for forming the source/drain regions is p-type, then a PMOSFET (p-channel) transistor device is formed. Integrated circuit devices utilize either n-channel devices exclusively, p-channel devices exclusively, or a combination of both on a single monolithic substrate.

Transistor gate conductors are defined using a photolithography process. In the photolithography process, a photosensitive film, i.e., photoresist, is spin-deposited across the polysilicon material. An optical image is transferred to the photoresist by projecting a form of radiation, typically ultraviolet light, through the transparent portions of a mask plate. A photochemical reaction alters the solubility of the regions of the photoresist exposed to the radiation. The photoresist is washed with a solvent known as developer to preferentially remove the regions of higher solubility, followed by curing the remaining regions of the photoresist. The remaining regions of the photoresist are highly resistant to attack by an etching agent that is capable of removing the polysilicon material. The portions of the polysilicon material left exposed by the photoresist are etched away to define gate conductors of ensuing transistor devices.

Unfortunately, the minimum lateral dimension that can be achieved for a patterned photoresist feature is limited by, among other things, the exposure of the radiation to the polysilicon material. For example, diffraction effects may undesirably occur as the radiation passes through slit-like transparent regions of the mask plate, scattering the radiation and therefore adversely affecting the resolution of the optical image. In addition, if the radiation exposure dosage is too great or not enough, the photoresist will be over-exposed or underexposed, respectively, thereby rendering inaccurate optical images. As such, the photoresist regions exposed to the radiation may fail to correspond to the mask plate pattern, resulting in the photoresist features being skewed. Consequently, the photolithography process limits the minimum achievable widths of the features of a conventional integrated circuit. It is therefore difficult to reduce the widths of and distances between, for example, transistor gate conductors, which are defined by the photolithography process.

Because of this limitation of the photolithography process, the pitch of, for example, transistor devices formed with conventional methods cannot be easily reduced. The “pitch” is herein defined as the distance between the same points of two adjacent structures of the same type, e.g., two adjacent gate conductors. Since the pitch of the integrated circuit devices cannot be easily reduced, the device integration cannot be increased to meet the high demand for smaller and faster integrated circuit devices. A need thus exists in the prior art to reduce the pitch of integrated circuit devices. A further need exists to develop a method for fabricating an integrated circuit in which the width of and distances between two adjacent structures of the same type are not limited by the photolithography process.

### SUMMARY OF THE INVENTION

The present invention addresses these needs by providing a method for reducing cell pitch, wherein the pitch of the formed devices can be reduced using current lithography processes to, for example, half that of conventional devices. Since the pitch of the devices can be reduced, the device integration can be increased, resulting in smaller and faster integrated circuits.

In a preferred embodiment, a pad oxide layer is formed on a substrate, and a silicon nitride layer is formed on the pad oxide layer. A trimmed photoresist layer is formed on the silicon nitride layer, and the silicon nitride layer is etched using the trimmed photoresist layer as an etch mask. The trimmed photoresist layer is removed until the silicon nitride layer is completely exposed, and an exposed portion of the pad oxide layer is removed until a portion of the substrate is exposed. A gate oxide layer is formed on the exposed portion of the substrate. A poly layer is deposited over the silicon nitride layer and the gate oxide layer, and the poly layer is etched back to expose the silicon nitride layer and to form a plurality of poly gates. Then, the silicon nitride layer is removed.

In another embodiment, a method for forming a semiconductor device having a reduced pitch comprises providing a substrate having a first insulating layer formed thereon and forming a second insulating layer on the first insulating layer. A photoresist layer is then formed on the second insulating layer. The second insulating layer is etched using the trimmed photoresist layer as an etch mask, and the photoresist layer is thereafter removed. An exposed portion of the first insulating layer is removed, and a third insulating layer is formed on an exposed portion of the substrate. A conductive layer is deposited on the second insulating layer and the third insulating layer, and the conductive layer is etched back to expose the second insulative layer and to form a plurality of gates. Thereafter, the second insulating layer is removed.

Any feature or combination of features described herein is included within the scope of the present invention provided that the features included in any such combination are not mutually inconsistent as will be apparent from the context, this specification, and the knowledge of one of ordinary skill in the art. For purposes of summarizing the present invention, certain aspects, advantages and novel features of the present invention have been described herein. Of course, it is to be understood that not necessarily all such aspects, advantages or features will be embodied in any particular embodiment of the present invention. Additional advantages and aspects of the present invention are apparent in the following detailed description and claims.

### BRIEF DESCIRPTION OF THE FIGURES

FIG. 1 is a cross-sectional view of a pad oxide layer formed on a substrate, a silicon nitride layer formed on the pad oxide layer, and a patterned photoresist layer formed on the silicon nitride layer in accordance with a preferred embodiment of the present invention;

FIG. 2 is a cross-sectional view of the configuration depicted in FIG. 1 wherein the patterned photoresist layer is trimmed by etching to reduce the size of the patterned photoresist layer in accordance with a preferred embodiment of the present invention;

FIG. 3 is a cross-sectional view of the configuration depicted in FIG. 2 wherein exposed parts of the silicon nitride layer are removed using the patterned photoresist layer as an etch mask in accordance with a preferred embodiment of the present invention;

FIG. 4 is a cross-sectional view of the configuration depicted in FIG. 3 wherein the patterned photoresist layer is removed in accordance with a preferred embodiment of the present invention;

FIG. 5 is a cross-sectional view of the configuration depicted in FIG. 4 wherein exposed parts of the pad oxide layer are removed in accordance with a preferred embodiment of the present invention;

FIG. 6 is a cross-sectional view of the configuration depicted in FIG. 5 wherein a gate oxide layer is formed on the exposed substrate in accordance with a preferred embodiment of the present invention;

FIG. 7 is a cross-sectional view of the configuration depicted in FIG. 6 wherein a poly layer is deposited on the silicon nitride layer and the gate oxide layer;

FIG. 8 is a cross-sectional view of the configuration depicted in FIG. 7 showing the poly layer being etched back to expose the silicon nitride layer;

FIG. 9 is a cross-sectional view of the configuration depicted in FIG. 8 wherein the silicon nitride layer is removed to form a plurality of poly gates having a reduced pitch.

### DETAILED DESCRIPTION OF THE PRESENTLY PREFERRED EMBODIMENTS

Reference will now be made in detail to the presently preferred embodiments of the invention, examples of which are illustrated in the accompanying drawings. Wherever possible, the same or similar reference numbers are used in the drawings and the description to refer to the same or like parts. It should be noted that the drawings are in simplified form and are not to precise scale. In reference to the disclosure herein, for purposes of convenience and clarity only, directional terms, such as, top, bottom, left, right, up, down, over, above, below, beneath, rear, and front, are used with respect to the accompanying drawings. Such directional terms should not be construed to limit the scope of the invention in any manner.

Although the disclosure herein refers to certain illustrated embodiments, it is to be understood that these embodiments are presented by way of example and not by way of limitation. The intent of the following detailed description, although discussing exemplary embodiments, is to be construed to cover all modifications, alternatives, and equivalents of the embodiments as may fall within the spirit and scope of the invention as defined by the appended claims. It is to be understood and appreciated that the process steps and structures described herein do not cover a complete process flow for the manufacture of poly gates having reduced cell pitches. The present invention may be practiced in conjunction with various photolithography techniques that are conventionally used in the art, and only so much of the commonly practiced process steps are included herein as are necessary to provide an understanding of the present invention. The present invention has applicability in the field of semiconductor devices and processes in general. For illustrative purposes, however, the following description pertains to methods for reducing the cell pitch in semiconductor devices.

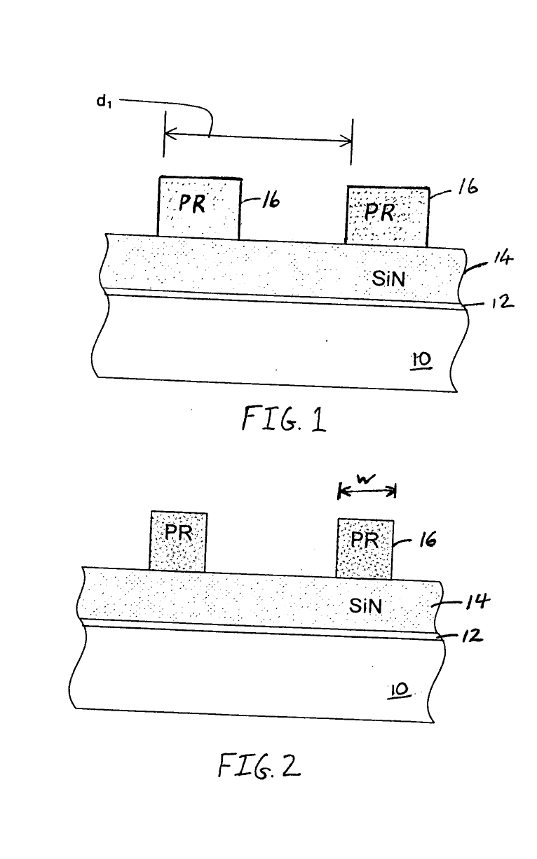

Referring more particularly to the drawings, FIG. 1 is a cross-sectional view of a pad oxide layer 12 formed on a substrate 10, a silicon nitride (SiN) layer 14 formed on the pad oxide layer 12, and a photoresist layer 16, e.g., a patterned photoresist layer, formed on the silicon nitride layer 14. Hence, the pad oxide layer 12, the silicon nitride layer 14, and the photoresist layer 16 are sequentially formed on the substrate 10. Preferably, the substrate 10 is made of a single crystalline silicon material. Alternatively, the substrate 10 can be made of materials such as gallium nitride (GaN), gallium arsenide (GaAs), or other materials commonly recognized as suitable semiconductor materials to those skilled in the art. The substrate 10 can be slightly doped with p-type dopants (e.g., arsenic, phosphorus, and antimony) or n-type dopants (e.g., boron and boron difluoride). The pad oxide layer 12 is preferably an insulating layer made of a dielectric material, e.g., a silicon dioxide (SiO₂) material, which may be formed by a thermal process such as thermal oxidation of the substrate 10. The pad oxide layer 12 can be formed to a thickness of between about 100 and about 300 angstroms (Å). In one embodiment, during thermal oxidation, the substrate 10 is exposed to thermal radiation in an oxygen-bearing ambient to form the pad oxide layer 12 on the substrate 10. Alternatively, the pad oxide layer 12 can be made of another dielectric material recognized as suitable to those skilled in the art.

The silicon nitride layer 14 is preferably an insulating layer and may be formed on the pad oxide 12 by chemical vapor deposition (CVD). In one embodiment, the CVD might include the following process: introducing into a reaction chamber a silane (SiH₄) silicon source gas, introducing into the reaction chamber an ammonia (NH₃) nitrogen source gas, introducing into the reaction chamber a nitrogen (N₂) carrier gas, and maintaining within the reaction chamber a temperature of about 700 to 800 degrees centigrade and a pressure of about 0.2 and about 0.8 torr. In the illustrated embodiment, the silicon nitride layer 14 may be formed to a thickness of between about 1,000 and about 3,000 Å. In modified embodiments, other materials, such as oxy-nitride, may be used instead of or in addition to silicon nitride.

The photoresist layer 16 is formed on the silicon nitride layer 14 using a photolithography process. To form the photoresist layer 16, a layer of photoresist is first spun onto the silicon nitride layer 14. The substrate 10 is then placed into a patterning tool known as a stepper where it is aligned to a mask plate and exposed to ultraviolet (UV) radiation. The mask plate may only be large enough to cover a small portion of the substrate 10, in which case the stepper steps the substrate 10 through many quadrants, each of them being exposed in turn until the entire or desired portion of the substrate 10 has been exposed to UV radiation. The substrate 10 is then placed in a developer solution that dissolves portions of the photoresist that were exposed to the UV radiation, thereby yielding the patterned photoresist layer 16. In the illustrated embodiment, features of the patterned photoresist layer 16 are about 4 k angstroms (Å) high and about 0.15 um wide. Also, in the illustrated embodiment, the minimum pitch size “d1” of the patterned photoresist layer 16 is as small as the photolithography process will allow. The width, height and/or pitch size “d1” may comprise other dimensions in other embodiments. Furthermore, in modified embodiments, other materials, such as patterned dielectrics (e.g., oxides), may be used instead of or in combination with the photoresist layer 16.

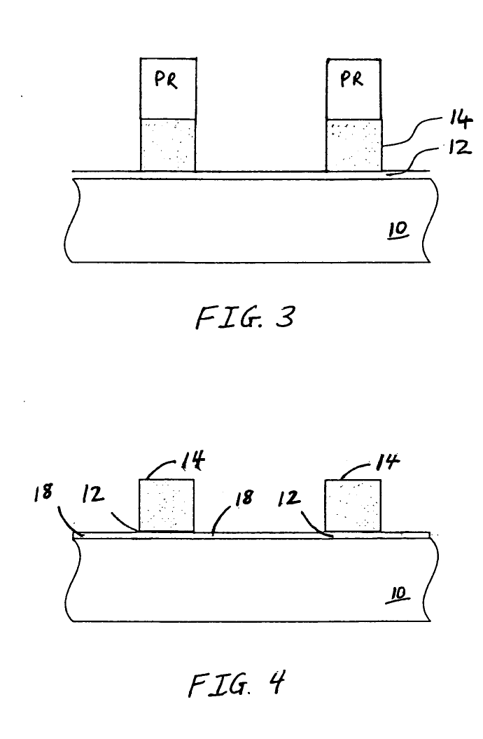

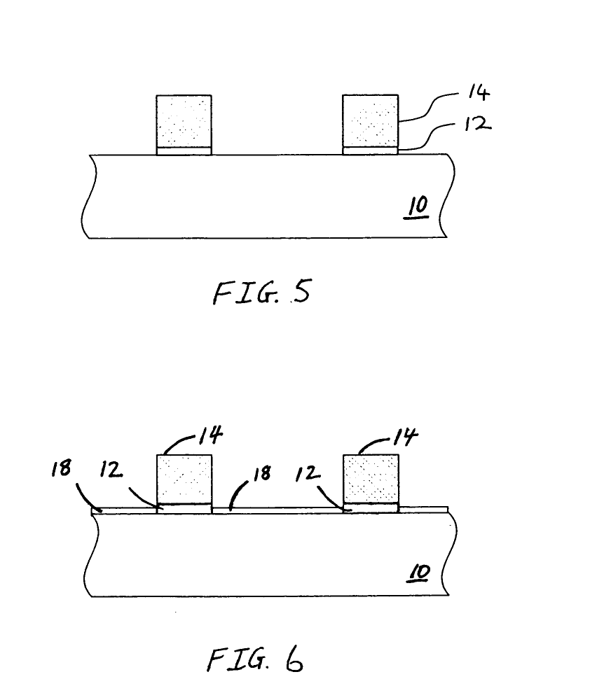

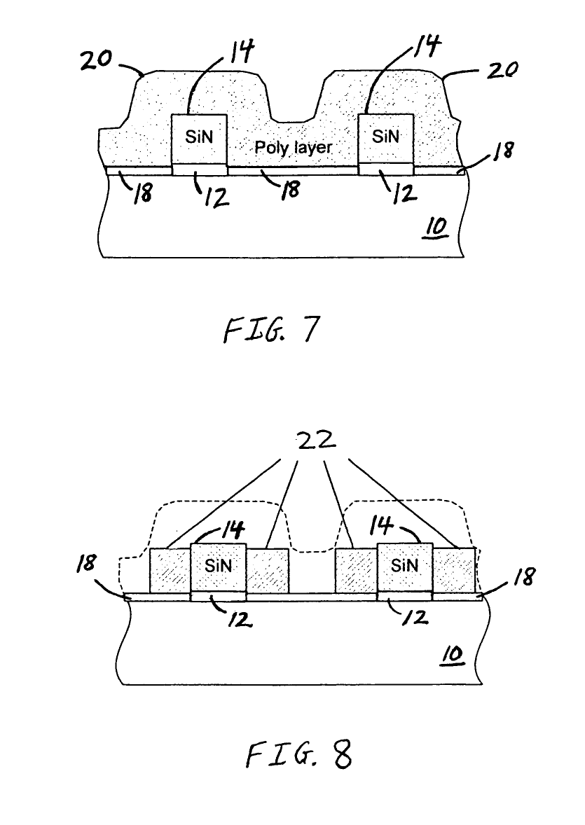

FIG. 2 is a cross-sectional view of the configuration depicted in FIG. 1, wherein the patterned photoresist layer 16 is trimmed by etching to reduce the size of the patterned photoresist layer 16 to thereby yield what can be referred to as a trimmed photoresist layer. Such a trimming operation can be carried out using a dry etch process, which can be performed, for example, in a chamber of a high-density plasma (HDP) etcher tool, and which can involve the introduction of oxygen (O₂) and hydrogen bromide (HBr) gases into the chamber. The plasma source gas has a high etch rate to the patterned photoresist layer 16 and a relatively low etch rate to the silicon nitride layer 14. As presently embodied, the patterned photoresist layer 16 is etched to a width “w” of about 0.075 um and a height of about 3 k angstroms (Å). In accordance with one aspect of the present invention, the width of the patterned photoresist layer 16 may be trimmed down by about 1% to about 50%. In one embodiment, the etch duration is selected to terminate before substantial portions of the silicon nitride layer 14 are removed. Using the trimmed photoresist layer 16 as an etch mask, the silicon nitride layer 14 is etched with an etchant having a higher selectivity for silicon than for dielectric materials to yield the construction shown in FIG. 3. Specifically, as presently embodied, the etching is performed on the silicon nitride layer 14 on the condition that the etch rate of the silicon nitride layer 14 is higher than the etch rate of the pad oxide layer 12, and is stopped when the upper surface of the pad oxide layer 12 is exposed. This is similar to etching the silicon nitride layer 14 using the pad oxide layer 12 as an etch stopper. In a preferred embodiment, the etchant is a plasma source gas that may vary in composition and may comprise, for example, CH3F/CF4/Ar/O2. Alternatively, a wet etching process using phosphoric acid or the like may be performed to remove the silicon nitride layer 14. Turning to FIG. 4, the trimmed photoresist layer 16 can be removed using a dry stripping method, which uses plasma gases, such as O₃ and O₃/N₂O, or a wet stripping method, which uses acids, such as H₂SO₄/H₂O₂, or organic solvents. The various dry and wet stripping methods that can be implemented are well-known etching techniques. Thereafter, as shown in FIG. 5, the exposed portions of the pad oxide layer 12 are removed using a well-known wet etching technique, implementing, for example, BOE as the etchant. The pad oxide layer 12 is etched for a time sufficient to completely remove the exposed portions of the pad oxide layer 12, at which point the wet etching technique is terminated before substantial portions of the substrate 10 are removed. Removal of the exposed portions of the pad oxide layer 12 exposes portions of the substrate 10. Referring to FIG. 6, a gate oxide layer 18 is preferably an insulating layer made of a dielectric material, is formed on the upper surface of the exposed portions of the substrate 10 to a thickness, for example, of between about 20 and 70 Å, and is most commonly formed by a thermal process such as by thermal oxidation of the substrate 10. In a preferred embodiment, the gate oxide layer 18 is made of a SiO₂ material. In one embodiment, during thermal oxidation, the substrate 10 is exposed to thermal radiation in an oxygen-bearing ambient to form the gate oxide layer 18 on the upper surface of the substrate 10. The gate oxide layer 18 can be made of another dielectric material recognized as suitable to those skilled in the art. Alternatively, a gate oxide film is deposited on the upper surface of the substrate 10 to form the gate oxide layer 18. Subsequently, as shown in FIG. 7, a poly layer 20 is deposited on the substrate 10 (configuration depicted in FIG. 6) to cover the silicon nitride layer 14 and the gate oxide layer 18. The poly layer 20 can be a polysilicon layer that is spin-deposited to a level, e.g., thickness, determined by the size, e.g., thickness, of an expected poly gate. For example, if the expected poly gate is to have a thickness of about 2 k angstroms (Å), then the poly layer 20 can be formed to a thickness of at least about 2 k angstroms (Å). In one embodiment, a deposited thickness of the poly layer 20 will be about equal to the thickness of the silicon nitride layer 14. The poly layer 20 can be any conductive or semi-conductive layer such as tungsten silicide.

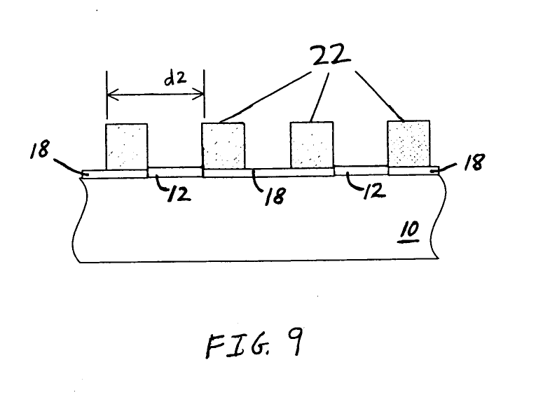

FIG. 8 is a cross-sectional view of the configuration depicted in FIG. 7 showing the poly layer 20 being etched back to form a plurality of poly gates 22. In one embodiment, a poly gate 22 is formed on each side of the silicon nitride layer 14, as depicted in FIG. 8. The poly layer 20 is etched with an etchant having a higher selectivity for silicon than for dielectric materials. In one embodiment, the selected etchant has a higher selectivity for the poly layer 20 than for the silicon nitride layer 14, and in another embodiment, the selected etchant has a higher selectivity for the poly layer 20 than for the silicon nitride layer 14 and the gate oxide layer 18. In a preferred embodiment, the etchant is a plasma source gas that may vary in composition and may comprise, for example, HBr/O2.

The poly layer 20 is etched for a time sufficient to form the plurality of poly gates 22. and to remove portions of the poly layer 20, at which point the plasma etch is terminated before substantial portions of the gate oxide layer 18 are removed. In accordance with one aspect, the poly layer 20 is etched for a time sufficient to expose the silicon nitride layer 14 and/or the gate oxide layer 18. In one embodiment, the thicknesses of the silicon nitride layer 14 and of the poly layer 20 are chosen so that, when the poly layer 20 is etched down to expose the silicon nitride layer 14 and/or the gate oxide layer 18, poly gates 22 are formed in desired shapes, e.g., thicknesses. The silicon nitride layer 14 is removed using, e.g., a wet etch technique, resulting in the formation of the plurality of poly gates 22 having a reduced pitch, as depicted in FIG. 9. Following the removal of the silicon nitride layer 14, transistor devices may be formed, for example, by implanting dopants into the source/drain junctions of the substrate 10, which are located between the plurality of poly gates 22. In a preferred embodiment, the spacing between pairs of adjacent poly gates 22 is relatively constant. The distance “d2” represents the pitch of the poly gates 22, and thus of ensuing transistor devices formed in accordance with the present invention. A comparison of pitch “d1” in FIG. 1 and pitch “d2” in FIG. 9 reveals that pitch “d2” is about half of pitch “d1”. Moreover, it can also be seen from a comparison of FIG. 1 and FIG. 9 that a lateral width of each poly gate is substantially less than a minimum lateral width that the photolithography process will allow. Therefore, the present invention can provide a method for forming transistor devices having less pitch than the pitch of conventional transistor devices formed using current photolithography conditions. Since the pitch of the devices can be reduced, the device integration can be increased.

In view of the foregoing, it will be understood by those skilled in the art that the methods of the present invention can facilitate formation of semiconductor devices, and in particular semiconductor devices having reduced cell pitches. The above-described embodiments have been provided by way of example, and the present invention is not limited to these examples. Multiple variations and modification to the disclosed embodiments will occur, to the extent not mutually exclusive, to those skilled in the art upon consideration of the foregoing description. Additionally, other combinations, omissions, substitutions and modifications will be apparent to the skilled artisan in view of the disclosure herein. Accordingly, the present invention is not intended to be limited by the disclosed embodiments, but is to be defined by reference to the appended claims.

1. A method, comprising:
providing a substrate having a plurality of features comprising a first material;
forming a layer over the substrate and the plurality of features, the layer comprising a second material;
removing the layer down to upper surfaces of the plurality of features, thereby exposing the plurality of features; and
removing the plurality of features.

2. The method as set forth in claim 1, wherein:
the removing of the plurality of features leaves behind portions of the layer; and
a pitch of adjacent features of the plurality of features, measured before the plurality of features is removed, is greater than a pitch of adjacent portions of the layer.

3. The method as set forth in claim 1, wherein:
the second material comprises polysilicon; and
the removing of the layer down to upper surfaces of the plurality of features forms a plurality of gates.

4. The method as set forth in claim 1, wherein:
the providing of a substrate includes providing a substrate having a first dielectric disposed thereon, the first dielectric being disposed between the substrate and the plurality of features; and
the forming of a layer over the substrate includes forming a second dielectric on the substrate and forming the layer on the second dielectric, so that the second dielectric is disposed between the substrate and the layer.

5. The method as set forth in claim 1, wherein:
the providing of a substrate includes providing a substrate having a first dielectric disposed thereon and removing the first dielectric from areas not covered by the features; and
the forming of a layer over the substrate includes forming a second dielectric on the areas and forming the layer on both the second dielectric and the features, so that the second dielectric is disposed between the substrate and the layer.

6. The method as set forth in claim 2, wherein:
the first and second dielectrics comprise silicon dioxide; and
prior to the forming of a layer over the substrate, the first dielectric is removed from areas of the substrate not covered by the plurality of features and the second dielectric is deposited onto the areas.

7. The method as set forth in claim 3, wherein:
the removing of the plurality of features leaves behind portions of the layer; and
a pitch of adjacent features of the plurality of features, measured before the plurality of features is removed, is greater than a pitch of adjacent portions of the layer.

8. The method as set forth in claim 4, wherein:
the second material comprises polysilicon; and
the removing of the layer down to upper surfaces of the plurality of features forms a plurality of gates.

9. The method as set forth in claim 5, wherein:
the providing of a substrate having a plurality of features is preceded by using a photolithography process to form the plurality of features on the substrate; and
a pitch of adjacent features of the plurality of features is as small as the photolithography process will allow.

10. A structure formed using the method of claim 1.

11. A structure formed using the method of claim 2.

12. A structure formed using the method of claim 6.

13. A method for forming a semiconductor device having a reduced pitch, comprising:
providing a substrate having a first insulating layer formed thereon;
forming a material layer on the first insulating layer;
forming a photoresist layer on the material layer;
etching the material layer using the photoresist layer as an etch mask;
removing the photoresist layer;
removing an exposed portion of the first insulating layer;
forming a second insulating layer on an exposed portion of the substrate;
depositing a conductive layer over the material layer and second insulating layer;
etching back the conductive layer to expose the material layer; and
removing the material layer.

14. The method as set forth in claim 13, wherein:
the first insulating layer is a pad oxide;
the material layer comprises silicon nitride;
the second insulating layer is a gate oxide;
the conductive layer comprises polysilicon.

15. The method as set forth in claim 14, wherein:
the photoresist layer is a trimmed photoresist layer; and
the etching of the conductive layer forms a plurality of gates.

16. The method of claim 15, wherein:
the pad oxide layer is formed using a thermal process;
the forming of the silicon nitride layer on the pad oxide layer comprises using a chemical vapor deposition process; and
the forming of the trimmed photoresist layer on the silicon nitride layer comprises forming a patterned photoresist layer on the silicon nitride layer and etching the patterned photoresist layer.

17. The method of claim 16, wherein:
the etching of the patterned photoresist layer comprises etching the patterned photoresist layer at an etch rate that is greater than an etch rate at which the silicon nitride layer is etched;
the etching of the patterned photoresist layer is terminated before a substantial portion of the silicon nitride layer is removed; and
the etching of the silicon nitride layer comprises etching the silicon nitride layer at an etch rate that is greater than an etch rate at which the pad oxide is etched.

18. The method of claim 15, wherein:
the removing the trimmed photoresist layer comprises using a dry stripping process or a wet stripping process; and
the removing of the exposed portion of the pad oxide layer comprises using a wet etching process.

19. The method of claim 15, wherein an amount of the conductive layer deposited on the gate oxide layer is determined by an expected thickness of the plurality of gates.

20. A structure formed using the method of claim 13.

21. A structure formed using the method of claim 15.

22. A structure comprising:
a plurality of gate conductors laterally spaced apart on a substrate;
a plurality of first dielectric portions laterally spaced apart on the substrate, wherein first dielectric portions are laterally interspersed between gate conductors; and
a plurality of second dielectric portions, each of the second dielectric portions being disposed between the substrate and one of the gate conductors.

23. The structure as set forth in claim 22, wherein a pitch of the gate conductors is less than pitch that a photolithography process will allow.

24. The structure as set forth in claim 22, wherein a thickness of the first dielectric is different than a thickness of the second dielectric.

25. The structure as set forth in claim 22, wherein the first dielectric is a pad oxide and the second dielectric is a gate oxide.

26. The structure as set forth in claim 25, wherein the pad oxide is thicker than the gate oxide.
